(19) United States
(12) Patent Application Publication
(10) Pub. No.: US 2011/0188224 A1
(43) Pub. Date: Aug. 4, 2011

(54) ELECTRONIC DEVICE

(76) Inventors: Takahiro Sugai, Tokyo (JP); Takahisa Funayama, Tokyo (JP)

(21) Appl. No.: 12/903,060

(22) Filed: Oct. 12, 2010

(30) Foreign Application Priority Data
Jan. 29, 2010 (JP) 2010-019686

(51) Int. Cl. H05K 7/02

(52) U.S. Cl. 361/807; 174/541

(57) ABSTRACT

An electronic device includes: an insulting casing having a first wall part and a second wall part that extends in a direction intersecting the first wall part; a contained component contained in the casing and provided at the first wall part at a position in the vicinity of the second wall part; and a conductive adhesive provided at the first wall part and comprising a first end portion electrically connected to the contained component and a second end portion provided at a position different from that of the first end portion.

### CROSS-REFERENCE TO THE RELATED APPLICATION(S)

The present application is based upon and claims priority from prior Japanese Patent Application No. 2010-019686, filed on Jan. 29, 2010, the entire contents of which are incorporated herein by reference.

### FIELD

Embodiments described herein generally relate to an electronic device.

### BACKGROUND

Conventionally, there has been known a technique for forming a wiring by applying a conductive adhesive to an inner face of a casing serving as an insulator, and for forming an electric circuit by connecting a connector to the conductive adhesive constituting this wiring. An example of such configuration is disclosed in JP-A-2005-268521.

In the configuration disclosed in JP-A-2005-268521, a circuit component is directly bonded to the inner face of the casing. In this structure, when the casing is distorted due to an external force of some kind acting thereon, for example, a stress is caused in a bonded portion between the circuit component and wiring pattern, which might result in destruction or damage of the bonded portion.

### BRIEF DESCRIPTION OF THE DRAWINGS

A general configuration that implements the various features of the present invention will be described with reference to the drawings. The drawings and the associated descriptions are provided to illustrate embodiments of the invention and not to limit the scope of the invention.

FIG. 1 is a perspective view of a portable computer according to a first embodiment of the present invention.

FIG. 2 is an exploded perspective view illustrating a positional relationship between a casing, in which a plurality of signal wires and a plurality of adhesive-filled portions are formed, and a connector having connection terminals in the first embodiment of the present invention.

FIG. 3 is a cross-sectional view illustrating a state in which the connector is bonded via conductive adhesives to a connector-mounting region of the casing in the first embodiment of the present invention.

FIG. 4 is a cross-sectional view illustrating a positional relationship between the casing, in which the signal wires and adhesive-filled portions are formed, and the connector in the first embodiment of the present invention.

FIG. 5 is a cross-sectional view illustrating a state in which the signal wires formed in the casing and a printed circuit board are electrically connected to each other via a rubber connector in the first embodiment of the present invention.

FIG. 6 is a cross-sectional view taken along the line VI-VI of FIG.

FIG. 7 is a cross-sectional view illustrating a state in which the rubber connector is yet to be pressurized between the printed circuit board and a bottom wall of the casing in the first embodiment of the present invention.

FIG. 8 is an exploded perspective view illustrating a positional relationship between the casing, in which a plurality of the signal wires and a plurality of the adhesive-filled portions are formed, and the connector having the connection terminals in a second embodiment of the present invention.

FIG. 9 is a cross-sectional view illustrating a state in which the signal wires formed in the casing and the printed circuit board are electrically connected to each other via a rubber connector in the second embodiment of the present invention.

FIG. 10 is a diagram illustrating a peripheral structure of groove portions 100 in the portable computer illustrated in FIG. 2.

FIG. 11 is a diagram illustrating a peripheral structure of the groove portion in a first variation of the portable computer of the present invention.

FIG. 12 is a diagram illustrating a peripheral structure of the groove portion in a second variation of the portable computer of the present invention.

FIG. 13 is a diagram illustrating a peripheral structure of the groove portions in a second example of the portable computer of the present invention.

FIG. 14 is a diagram illustrating a peripheral structure of the groove portion in a third example of the portable computer of the present invention.

FIG. 15 is a diagram illustrating a peripheral structure of the groove portion in a fourth example of the portable computer of the present invention.

### DETAILED DESCRIPTION

According to the embodiments described herein, there is provided an electronic device including: an insulting casing having a first wall part and a second wall part that extends in a direction intersecting the first wall part; a contained component contained in the casing and provided at the first wall part at a position in the vicinity of the second wall part; and a conductive adhesive provided at the first wall part and comprising a first end portion electrically connected to the contained component and a second end portion provided at a position different from that of the first end portion.

Embodiments according to the present invention will be described in detail with reference to the accompanying drawings. The scope of the claimed invention should not be limited to the examples illustrated in the drawings and those described in below.

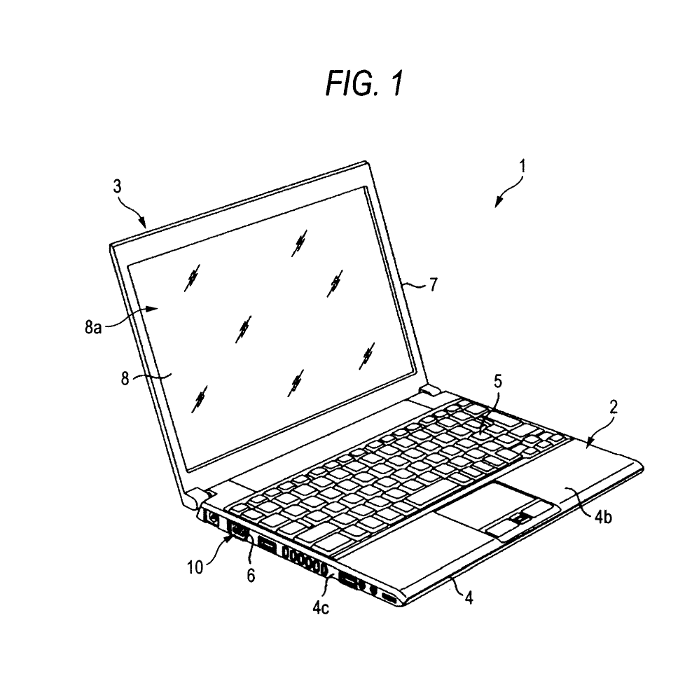

Hereinafter, an embodiment of the present invention will be described with reference to FIGS. 1 to 7.

FIG. 1 discloses a portable computer 1 that is one example of an electronic device. The portable computer 1 includes: a main unit 2; and a display unit 3.

The main unit 2 includes a casing 4. The casing 4 is formed by molding a synthetic resin material, for example, and has an electrical insulation property. The casing 4 is formed into a flat box shape having: a bottom wall 4a; an upper wall 4b; and a lateral wall 4c. The upper wall 4b of the casing 4 supports a keyboard 5. The lateral wall 4c is extended upward from a lateral edge of the bottom wall 4a. The lateral wall 4c of the casing 4 is provided with a rectangular opening 6.

As illustrated in FIG. 1, the display unit 3 includes: a display casing 7; and a liquid crystal display panel 8 contained in this display casing 7. The display casing 7 is formed into a flat box shape having substantially the same size as the main unit 2. The liquid crystal display panel 8 has a screen 8a on which image information and/or character information are/is displayed. The screen 8a is exposed to outside of the display casing 7 through a front face of the display casing 7.

The display unit 3 is supported at a rear end portion of the main unit 2 via unillustrated hinges. Therefore, the display unit 3 is rotatable between: a closed position at which the display unit 3 lies on the main unit 2 so as to cover the keyboard 5; and an opened position at which the display unit 3 rises from the closed position with respect to the rear end portion of the main unit 2 so as to expose the keyboard 5 and the screen 8a.

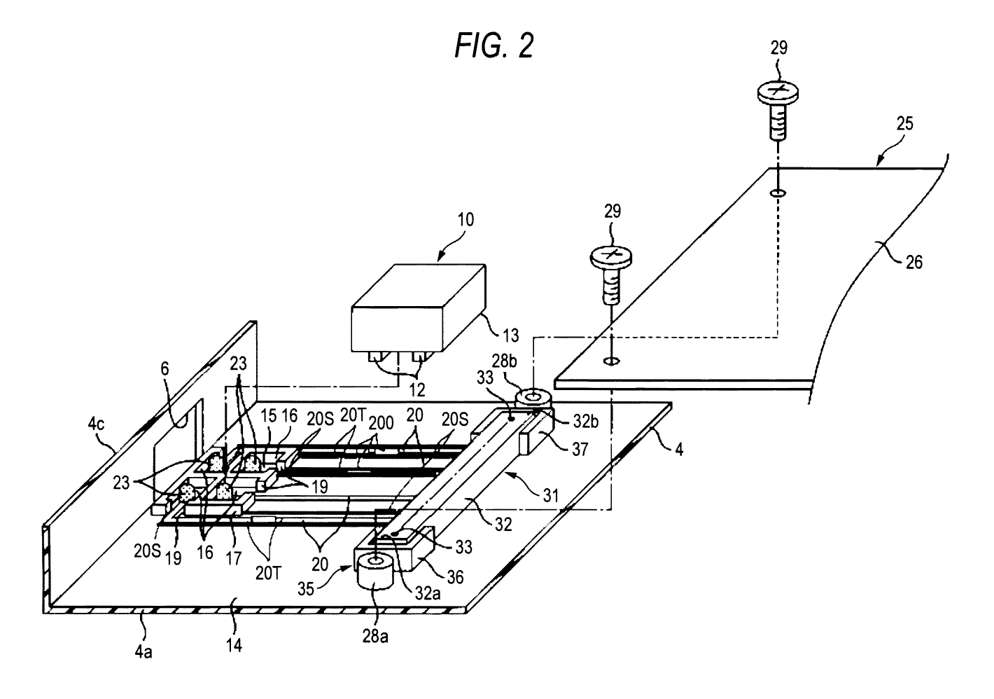

As illustrated in FIGS. 1 and 2, a connector 10 is located inside the rectangular opening 6 of the lateral wall 4c. The connector 10 is provided to connect with a peripheral device (not illustrated) such as an external monitor, for example. The connector 10 has a plurality of connection terminals 12. The connection terminals 12 are arranged in a grid layout at a flat lower face 13 of the connector 10.

The connector 10 is supported over an inner face 14 of the bottom wall 4a of the casing 4. The inner face 14 of the casing 4 has a connector-mounting region 15. The connector-mounting region 15 is a region, through which the connector 10 is fixed to the casing 4, and is adjacent to the opening 6.

As illustrated in FIGS. 2 to 4, a plurality of adhesive-filled portions 16 are provided in the connector-mounting region 15. The adhesive-filled portions 16 are defined in a grid pattern by a partition wall 17 so as to conform to the connection terminals 12 of the connector 10. The partition wall 17 forms a rib shape protruded from the inner face 14 of the bottom wall 4a toward the inside of the casing 4, and surrounds each adhesive-filled portion 16. Each adhesive-filled portion 16 is opened upward from the bottom wall 4a, and has a shape larger than that of the associated connection terminal 12 of the connector 10.

The partition wall 17 includes a plurality of wiring introduction portions 19. The wiring introduction portions 19 form slit shapes opened in the respective adhesive-filled portions 16. Through positions corresponding to the wiring introduction portions 19, the inner face 14 of the bottom wall 4a is exposed.

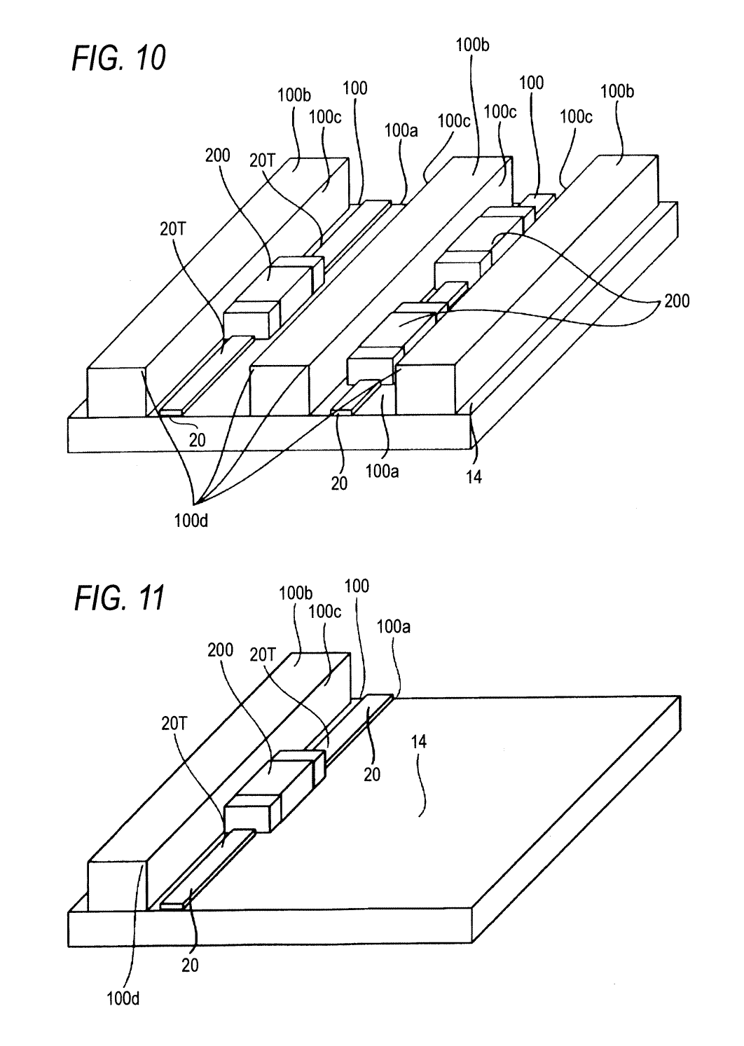

As illustrated in FIG. 2, the inner face 14 of the bottom wall 4a is integrally provided with a plurality of signal wires 20. The signal wires 20 are formed by applying conductive adhesives to the inside of groove portions 100, provided at the inner face 14 of the bottom wall 4a, so that the conductive adhesives are embedded in line patterns in the groove portions 100. The groove portions 100 are extended in a width direction of the casing 4, and located in parallel with each other at intervals. As a method for applying conductive adhesives to the inner face 14 of the bottom wall 4a, a screen printing method or a dispense method, for example, may be used. It should be noted that structures of the groove portions 100 in the present invention will be described later with reference to FIGS. 10 to 15.

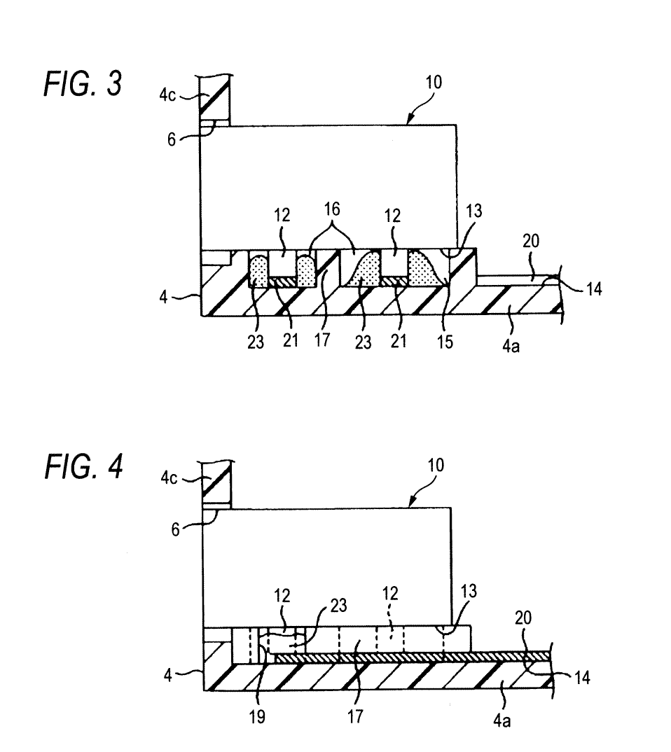

One ends of the signal wire 20 are inserted into the adhesive-filled portions 16 through the wiring introduction portions 19 of the partition wall 17. At one ends of the signal wires 20, lands 21 illustrated in FIG. 3 are formed. The lands 21 are located at the bottom of the adhesive-filled portions 16.

As illustrated in FIGS. 3 and 4, the connector 10 is superposed on the partition wall 17. The lower face 13 of the connector 10 closes open ends of the adhesive-filled portions from above. Thus, the connection terminals 12 of the connector 10 are inserted into the adhesive-filled portions 16, and are stacked on the lands 21.

Conductive adhesives 23 are filled into the adhesive-filled portions 16. The conductive adhesives 23 are hardened in a state in which the connection terminals 12 and the lands 21 are integrally covered with the conductive adhesives 23. The conductive adhesives 23, filled into the adhesive-filled portions 16 adjacent to each other, are each maintained in an electrically insulated state by the partition wall 17.

Therefore, the connector 10 is maintained in a state in which the connector 10 is fixed to the connector-mounting region 15 of the casing 4 via the conductive adhesives 23 and the connection terminals 12 of the connector 10 are electrically connected to the lands 21 of the associated signal wires 20.

As illustrated in FIG. 2, other ends of the signal wires 20, opposite to the lands 21, are guided in a direction in which the other ends go away from the connector-mounting region 15, and are lined up at intervals on the inner face 14 of the bottom wall 4a.

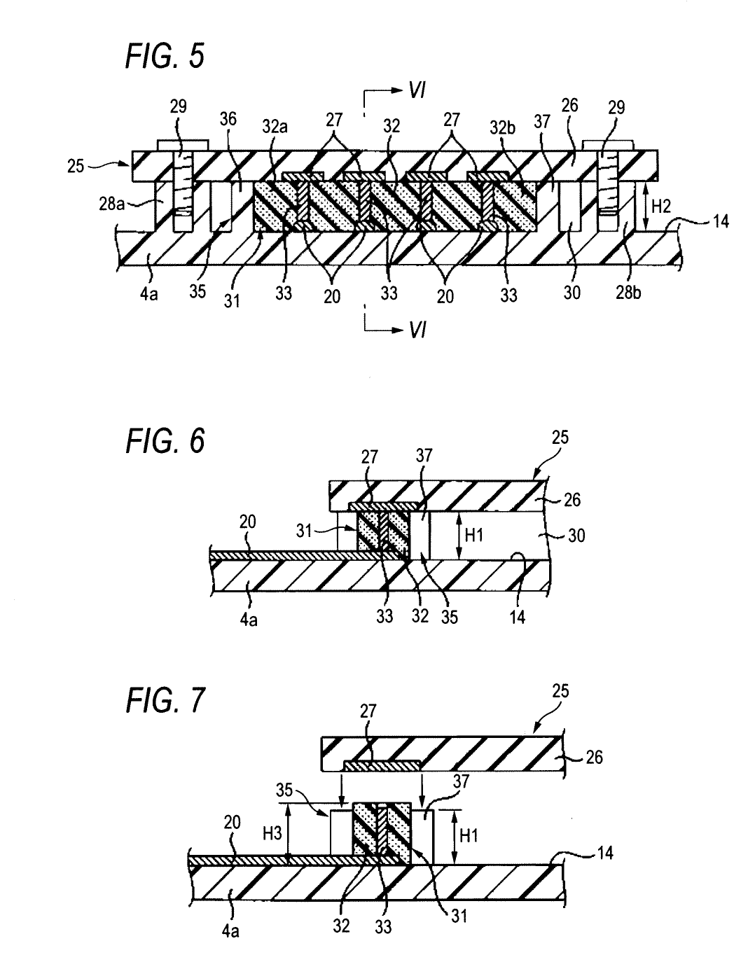

Moreover, a printed circuit board 25 is contained inside the casing 4. As illustrated in FIG. 5, the printed circuit board 25 has: a circuit board 26; and a plurality of pads 27 formed at one end of a lower face of this circuit board 26. The pads 27 each serve as an example of a terminal portion electrically continuous with a conductor pattern of the printed circuit board 25, and are lined up at intervals so as to correspond to the other ends of the signal wires 20.

One end of the circuit board 26 is fixed onto a pair of boss portions 28a and 28b, protruded from the inner face 14 of the bottom wall 4a, via screws 29 serving as fixtures. Therefore, the circuit board 26 is located in parallel with the inner face 14 of the bottom wall 4a, and a gap 30 equivalent in height to the boss portions 28a and 28b is formed between the circuit board 26 and the inner face 14 of the bottom wall 4a.

The pads 27 of the circuit board 26 are opposed to the other ends of the signal wires 20. The pads 27 and the other ends of the signal wires 20 are electrically connected to each other via a rubber connector 31. The rubber connector 31 is also referred to as an “elastic connector”, and is interposed between the bottom wall 4a of the casing 4 and one end of the circuit board 26.

As illustrated in FIGS. 5 to 7, the rubber connector 31 includes: a connector body 32; and a plurality of metal wires 33. The connector body 32 is formed of a rubber elastic body such as silicone rubber, for example, and has an elongated shape extended in a direction in which the connector body 32 traverses the other ends of the signal wires 20. Therefore, the connector body 32 has: a first end portion 32a; and a second end portion 32b located opposite to the first end portion 32a. The first and second end portions 32a and 32b are located away from each other in a longitudinal direction of the connector body 32.

The metal wires 33 each serve as an example of a conductor, and are embedded integrally in the connector body 32 so as to pass through the connector body 32 in its thickness direction. Moreover, the metal wires 33 are lined up at intervals in the longitudinal direction of the connector body 32.

The connector body 32 is compressed in the thickness direction between the bottom wall 4a of the casing 4 and the circuit board 26. With this compression, one ends of the metal wires 33 are brought into contact with the signal wires 20, while the other ends of the metal wires 33 are brought into contact with the pads 27. Hence, the other ends of the signal wires 20 and the pads 27 are electrically connected to each other via the metal wires 33.

As illustrated in FIGS. 2 and 5, the inner face 14 of the bottom wall 4a of the casing 4 is integrally provided with a holder part 35 for determining a position at which the rubber connector 31 is attached to the casing 4. The holder part 35 of the present embodiment has a first engagement portion 36 and a second engagement portion 37.

The first engagement portion 36 is formed into a rib shape protruded upward from the inner face 14 of the bottom wall 4a, and surrounds the first end portion 32a of the connector body 32 from three directions, thereby restraining the first end portion 32a. Similarly, the second engagement portion 37 is formed into a rib shape protruded upward from the inner face 14 of the bottom wall 4a, and surrounds the second end portion 32b of the connector body 32 from three directions, thereby restraining the second end portion 32b. Therefore, the first and second engagement portions 36 and 37 are located away from each other in the longitudinal direction of the connector body 32.

The connector body 32 is held by the holder part 35 so that the connector body 32 is placed between the first and second engagement portions 36 and 37, thus determining the positioning of the connector body 32 along the width and depth directions of the casing 4.

The first and second engagement portions 36 and 37 are located between the boss portions 28a and 28b to which the circuit board 26 is fixed. A height dimension H1 of each of the first and second engagement portions 36 and 37 is equivalent to a height dimension H2 of each of the boss portions 28a and 28b. Thus, in a state where the circuit board 26 is fixed to the boss portions 28a and 28b, upper ends of the first and second engagement portions 36 and 37 abut against the lower face of the circuit board 26 to receive the circuit board 26 in a direction away from the bottom wall 4a.

As illustrated in FIG. 7, the height dimension H1 of each of the first and second engagement portions 36 and 37 is set to be smaller than a thickness dimension H3 of the connector body 32 measured when the connector body 32 is in a free state prior to compression. Therefore, in a state where the circuit board 26 is yet to be fixed to the boss portions 28a and 28b as illustrated in FIG. 2, an upper end portion of the connector body 32 is projected upward from the upper ends of the first and second engagement portions 36 and 37.

Next, a procedure for establishing connections between the signal wires 20, printed on the bottom wall 4a of the casing 4, and the pads 27 of the printed circuit board 25 using the rubber connector 31 will be described.

First, the first end portion 32a of the connector body 32 is fitted into the first engagement portion 36 of the holder part 35, and the second end portion 32b of the connector body 32 is fitted into the second engagement portion 37 of the holder part 35. Thus, the position of the rubber connector 31 with respect to the bottom wall 4a of the casing 4 is determined. In a state where the positioning of the rubber connector 31 is determined, the upper end portion of the connector body 32 is projected upward from the first and second engagement portions 36 and 37 as illustrated in FIGS. 2 and 7.

Next, the printed circuit board 25 is fixed via the screws 29 to upper ends of the boss portions 28a and 28b protruded from the bottom wall 4a. With this fixation, the circuit board 26 of the printed circuit board 25 comes into contact with the upper end portion of the connector body 32, and presses the connector body 32 toward the bottom wall 4a of the casing 4.

As a result, the connector body 32 is compressed between the bottom wall 4a and the circuit board 26 in the thickness direction. Moreover, the lower face of the circuit board 26 abuts against the upper ends of the first and second engagement portions 36 and 37 of the holder part 35, and the circuit board 26 is received from below by the first and second engagement portions 36 and 37.

Thus, the distance between the circuit board 26 and the bottom wall 4a is determined, and the amount of compression of the connector body 32 is controlled. In other words, the first and second engagement portions 36 and 37 of the holder part 35 determine the position of the connector body 32 with respect to the bottom wall 4a of the casing 4, and concurrently restrict excessive compression of the connector body 32.

Upon compression of the connector body 32 between the circuit board 26 and the bottom wall 4a, one ends of the metal wires 33 come into contact with the signal wires 20 at an appropriate pressure. Similarly, the other ends of the metal wires 33 come into contact with the pads 27 of the printed circuit board 25 at an appropriate pressure. Hence, the signal wires 20 of the casing 4 and the printed circuit board 25 are maintained in an electrically connected state via the rubber connector 31.

According to the first embodiment described above, the holder part 35 for determining the position at which the connector body 32 is attached to the bottom wall 4a of the casing 4 is integrally provided at the casing 4 so as to be protruded from the inner face 14 of the bottom wall 4a. In addition, the height dimension H1 of each of the first and second engagement portions 36 and 37 of the holder part 35 is set to be smaller than the thickness dimension H3 of the connector body 32 measured prior to the compression.

Therefore, upon fixation of the circuit board 26 of the printed circuit board 25 onto the boss portions 28a and 28b, the upper ends of the first and second engagement portions 36 and 37 of the holder part 35 abut against the lower face of the circuit board 26, and restrict excessive compression of the connector body 32.

In other words, the height dimension H1 of each of the first and second engagement portions 36 and 37 of the holder part 35 is set so that the amount of compression of the connector body 32 is at an appropriate level, thus controlling the amount of compression of the connector body 32. Accordingly, while buckling of the metal wires 33 embedded in the connector body 32 is prevented, a contact pressure between the metal wires 33 and the signal wires 20 and a contact pressure between the metal wires 33 and the pads 27 can each be maintained at an appropriate level, thereby making it possible to increase the reliability of electric connection.

According to the first embodiment, the holder part 35 for controlling the amount of compression of the connector body 32 is integrally provided at the bottom wall 4a of the casing 4. Therefore, a dedicated connector holder for controlling the amount of compression of the rubber connector 31 can be eliminated, and the number of components of the portable computer 1 can be reduced.

In addition, since a dedicated constituent element for supporting the connector holder does not have to be added to the bottom wall 4a of the casing 4, the structure of the casing 4 is naturally simplified, and the number of man-hours required for assembly of the portable computer 1 can be reduced.

Hence, the first embodiment has advantages that the manufacturing cost of the portable computer can be reduced and the portable computer 1 can be provided at a low cost.

The present invention is not limited to the first embodiment, but may be implemented by making various modifications thereto without departing from the scope of the invention.

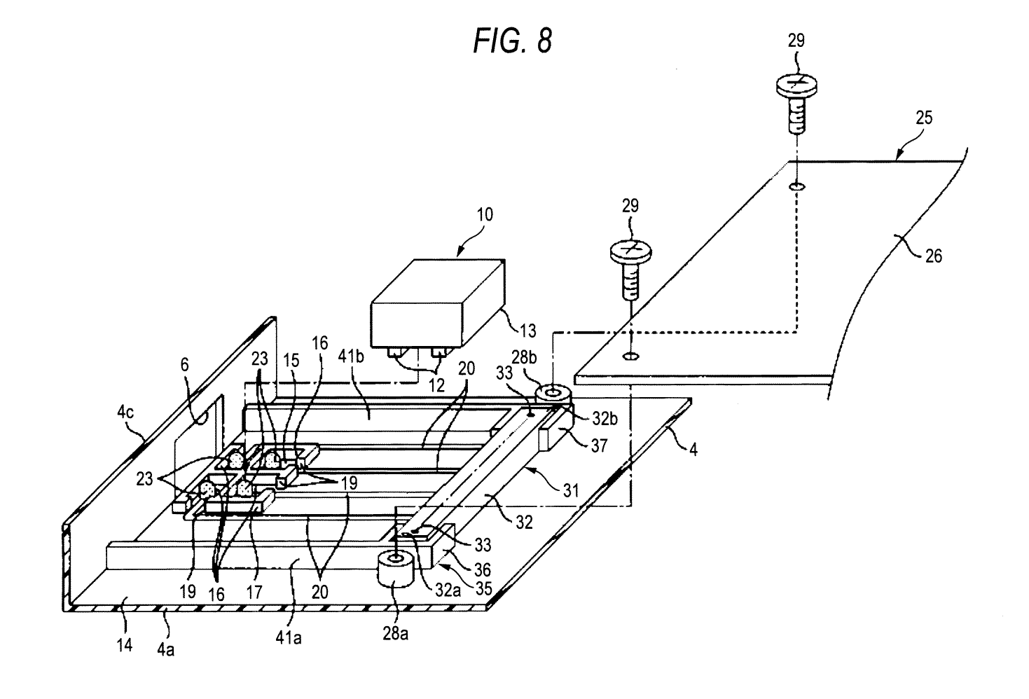

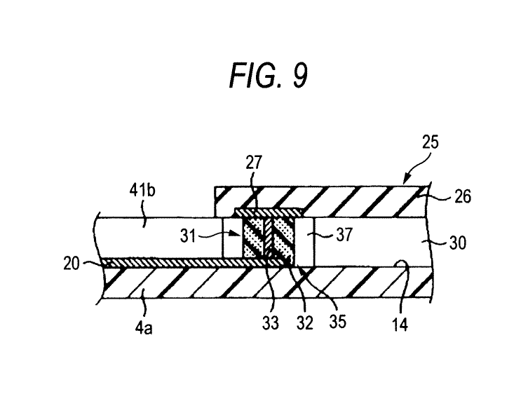

For example, FIGS. 8 and 9 disclose a second embodiment of the present invention. The second embodiment is different from the first embodiment in that the bottom wall 4a of the casing 4, provided with the signal wires 20, is reinforced. Other basic structures of the portable computer 1 of the second embodiment are similar to those of the portable computer 1 of the first embodiment. Therefore, in the second embodiment, the same constituent elements as those in the first embodiment are identified by the same reference characters, and the description thereof will be omitted.

As illustrated in FIG. 8, the inner face 14 of the bottom wall 4a of the casing 4 is integrally provided with a pair of convex portions 41a and 41b. The convex portions 41a and 41b are extended upward from the bottom wall 4a, and located in parallel with the signal wires 20 so as to run along the signal wires 20. In the present embodiment, the signal wires 20 are located between the convex portions 41a and 41b.

Furthermore, the convex portions 41a and 41b are arranged in parallel with each other at an interval so that the first engagement portion 36 of the holder part 35 and the lateral wall 4c of the casing 4 are connected to each other, and the second engagement portion 37 of the holder part 35 and the lateral wall 4c of the casing 4 are connected to each other. Accordingly, the first and second engagement portions 36 and 37 of the holder part 35 and the convex portions 41a and 41b constitute one-piece structures extended upward from the bottom wall 4a of the casing 4.

In such structures, the signal wires 20 are located between the convex portions 41a and 41b extended upward from the bottom wall 4a of the casing 4. Therefore, the convex portions 41a and 41b function as ribs for reinforcing regions of the bottom wall 4a, in which the signal wires 20 are formed. Hence, the rigidity of the bottom wall 4a is increased, thus making it difficult to cause distortion of the bottom wall 4a and making it possible to prevent disconnection and/or damage of the signal wires 20 provided at the bottom wall 4a by the conductive adhesives.

It should be noted that the convex portion may be formed between the adjacent signal wires. In this structure, the convex portions and signal wires are alternately arranged on the bottom wall, thus further increasing the rigidity of the bottom wall, and making it possible to protect each signal wire by the convex portions.

In the first embodiment, the casing is made of a synthetic resin material, but may alternatively be made of a metal material such as magnesium or aluminum, for example. When the casing is made of metal, an electrical insulation property may be imparted to the casing by coating the inner face of the casing with an insulating layer, and the signal wires may be provided on this insulating layer, for example.

Moreover, the holder part is not limited to the structure surrounding the first and second end portions of the connector body, but may be formed into a shape into which the connector body is entirely fitted, for example.

Next, referring to FIGS. 10 to 12, the structures of the groove portions 100 in the present example and first and second variations will be described. First, referring to FIG. 10, the structures of the groove portions 100 illustrated in FIG. 2 will be described. FIG. 10 is a diagram illustrating a peripheral structure of the groove portions 100 in the portable computer illustrated in FIG. 2.

As illustrated in FIG. 10, the inner face 14 of the casing 4 of the present example is provided with the groove portions 100 into which the signal wires 20 are formed and electronic components 200 such as resistor and capacitor are mounted. The signal wires 20 each have: a first end portion 20T electrically connected to the electronic component 200; and a second end portion 20S located opposite to this first end portion 20T. The second end portion 20S is electrically connected to the circuit board 26 and/or the connector 10. It should be noted that the second end portion 20S can also serve as a ground connected to a ground portion (not illustrated) provided at the inner face of the casing 4, for example. The groove portions 100 have: bottom wall parts 100a; protruded parts 100b; lateral wall parts 100c; and end portions 100d. Each bottom wall part 100a is a flat surface extending along the inner face 14. Each lateral wall part 100c is a flat surface extending along the inner face 14, and runs across the bottom wall part 100a and the inner face 14. Each end portion 100d is a tip region of the lateral wall part 100c.

Each protruded part 100b has a shape protruded from the bottom wall part 100a toward the inner portion of the casing 4. The height of each protruded part 100b, i.e., the distance between each protruded part 100b and the bottom wall part 100a, is greater than the height of each signal wire 20. Accordingly, as illustrated in FIG. 10, the signal wires 20 and the electronic components 200 are provided so as to be entirely contained in the groove portions 100.

In the above-described structure, even if a contained component, which is provided on the periphery of the groove portion 100 and is not fixed in place or in position, for example, comes into contact with the inner face 14, the possibility of removal of the electronic component 200 and/or disconnection of the signal wire 20 can be reduced. It should be noted that although an example in which the respective protruded parts 100b are provided to have substantially the same height has been described above, the present invention is not limited to this example. Alternatively, there may be provided a structure in which the signal wires 20 are not protruded toward the inner portion of the casing 4 beyond the inner face 14 or the protruded parts 100b.

In each groove portion 100 of the present example, a pair of the lateral wall parts 100c running from the bottom wall 4a are each extended upward so as to be substantially orthogonal to the bottom wall 4a, but the present invention is not limited to this. For example, when the lateral wall parts 100c are formed so that the width of the bottom wall part 100a is greater than the distance between a pair of the end portions 100d, i.e., when a pair of the lateral wall parts 100c have a shape extended so to as to be expanded toward the inner portion of the casing 4 from the bottom wall part 100a, the step of applying the signal wires 20 is simplified.

This shape is effective when the signal wires 20 are arranged and/or the electronic components 200 are mounted in regions, e.g., a corner portion of the casing 4 and an area adjacent to the lateral wall part, having a structure in which it is difficult to apply the signal wires 20 and/or having a structure in which it is difficult to mount the electronic components 200, for example.

On the other hand, for example, when the lateral wall parts 100c are formed so that the width of the bottom wall part 100a is smaller than the distance between a pair of the end portions 100d, i.e., when a pair of the lateral wall parts 100c have a shape extended so as to be narrowed toward the inner portion of the casing 4 from the bottom wall part 100a, the signal wires 20 and/or the electronic components 200 can be more firmly protected. This shape is effective when the signal wires 20 and/or the electronic components 200 are provided in a region where contained components, which are not fixed in place or in position, are densely provided, for example. Thus, the signal wires 20 can be more suitably arranged by optionally using the above-described structures in accordance with the positions at which the signal wires 20 are provided.

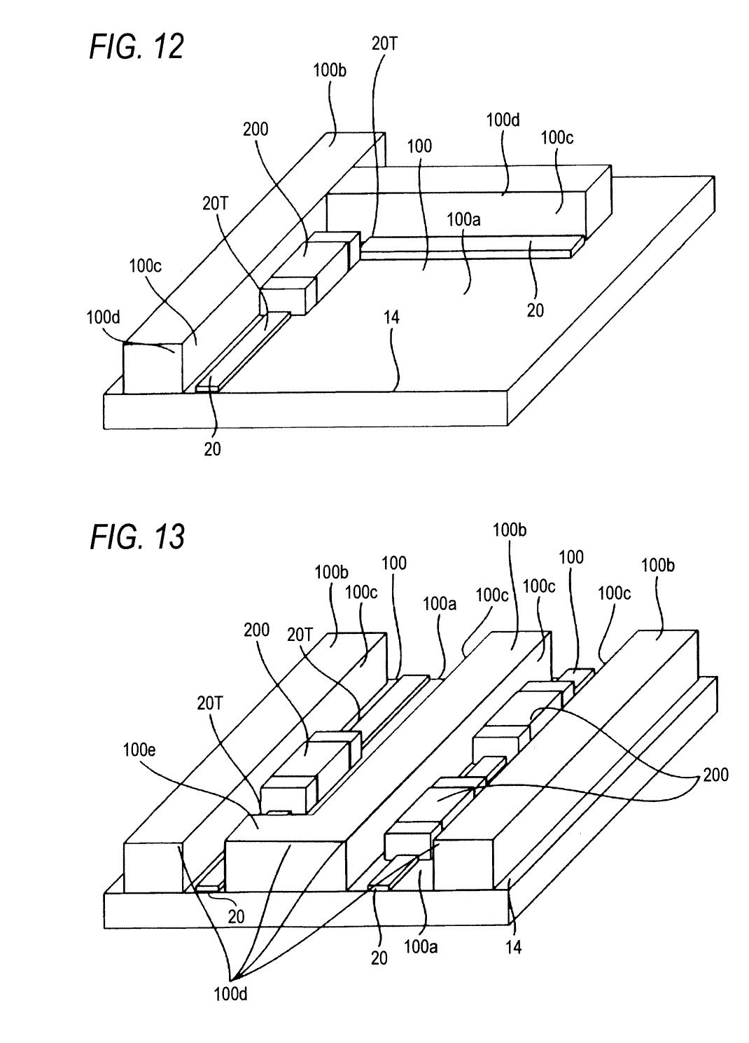

Next, referring to FIGS. 11 and 12, the variations of the present embodiment will be described. FIG. 11 is a diagram illustrating a peripheral structure of the groove portion in the first variation of the portable computer according to the present embodiment. FIG. 12 is a diagram illustrating a peripheral structure of the groove portion in the second variation of the portable computer according to the present embodiment. It should be noted that components having functions, which are the same as or similar to those of the components of the first embodiment, are identified by the same reference characters, and the description thereof will be omitted. Furthermore, structures other than those described below are similar to those of the first embodiment.

First, referring to FIG. 11, the first variation of the present example will be described. As illustrated in FIG. 11, in the first variation of the present example, the protruded part 100b of the groove portion 100 is provided at only one side. In other words, there is provided a structure in which the lateral wall part 100c protects the signal wire 20 and the electronic component 200 from one direction. In such a structure, effects similar to those of the first embodiment are obtainable. Further, the distance between a pair of the protruded parts 100b will not be determined in accordance with the width of the signal wire 20 or the electronic component 200. For example, this structure may be realized by utilizing a step and/or a rib provided at the inner face of the casing 4.

Next, referring to FIG. 12, the second variation of the present example will be described. As illustrated in FIG. 12, in the second variation of the present example, a pair of the protruded parts 100b of the groove portion 100 are provided so as to correspond to a corner portion of the electronic component 200. In other words, a pair of the protruded parts 100b are extended substantially orthogonally along adjacent side portions of the electronic component 200. In such a structure, effects similar to those of the first embodiment are obtainable, and the electronic component 200 can be more firmly protected with respect to the direction intersecting the direction of extension of the groove portion 100.

Next, referring to FIG. 13, a second example of the present embodiment will be described. FIG. 13 is a diagram illustrating a peripheral structure of the groove portions in the second example of the portable computer. It should be noted that components having functions, which are the same as or similar to those of the components of the first embodiment, are identified by the same reference characters, and the description thereof will be omitted. Furthermore, structures other than those described below are similar to those of the first embodiment.

As illustrated in FIG. 13, in the portable computer of the second example, there is provided a wiring protection part 100e that extends from the protruded part 100b of the casing 4 so as to narrow the groove portion 100, and that protects the signal wire 20 in accordance with the width of the signal wire 20. Thus, in this example, even when the groove portion 100 is formed in accordance with the electronic component 200 having a relatively wide width with respect to the signal wire 20, the signal wire 20 can be suitably protected.

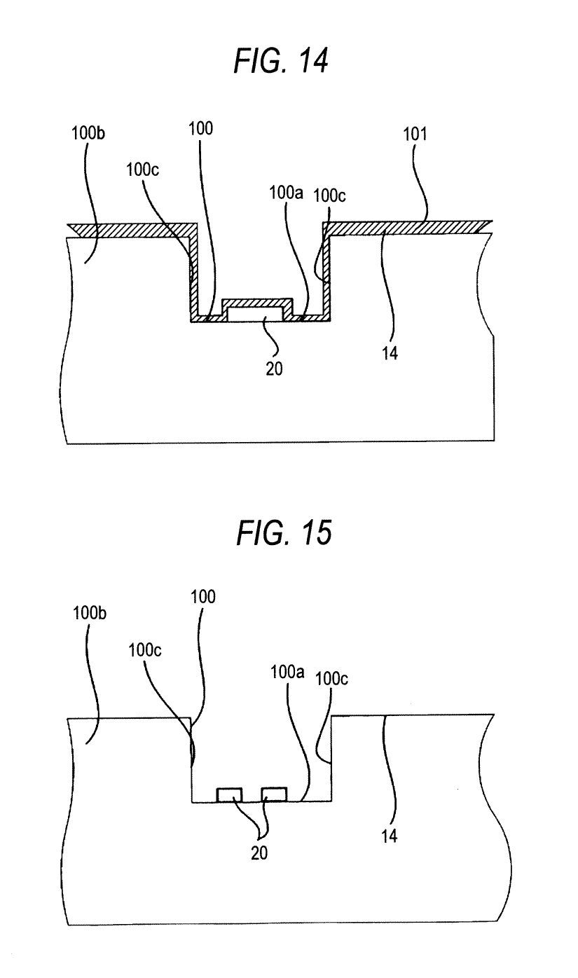

Next, referring to FIG. 14, a third example of the present embodiment will be described. FIG. 14 is a diagram illustrating a peripheral structure of the groove portion in the third example of the portable computer. It should be noted that components having functions, which are the same as or similar to those of the components of the first embodiment, are identified by the same reference characters, and the description thereof will be omitted. Furthermore, structures other than those described below are similar to those of the first embodiment.

As illustrated in FIG. 14, in the portable computer of the third example, the inner face of the casing 4 is provided with a seal member 101. The seal member 101 includes a thin insulating film member and/or insulating coating, for example, and functions as an insulating layer. In this example, since the seal member 101 is provided, the signal wire 20 will not be exposed to the inner face 14 of the casing 4, and the signal wire 20 can be more firmly protected.

Next, referring to FIG. 15, a fourth example of the present embodiment will be described. FIG. 15 is a diagram illustrating a peripheral structure of the groove portion in the fourth example of the portable computer. It should be noted that components having functions, which are the same as or similar to those of the components of the first embodiment, are identified by the same reference characters, and the description thereof will be omitted. Furthermore, structures other than those described below are similar to those of the first embodiment.

As illustrated in FIG. 15, in the portable computer of the fourth example, there are provided a plurality of the signal wires 20 between a pair of the lateral wall parts 100c of the casing 4. In such a structure, even when a differential circuit, for example, is formed at the inner face 14 of the casing 4, the signal wires 20 can be suitably protected.

Although preferred embodiments of the present invention have been described thus far, the present invention is not limited to the foregoing embodiments, but various modifications may be made to the present invention. For example, the present invention may be implemented as an electronic device including an electric circuit in which a general surface, a top face of a rib and a bottom face of a concave groove are provided as the inner face of the casing and conductive adhesives are applied to all of the general surface, top face and bottom face. In this case, the electric circuit having a more complicated circuit configuration can be formed, and furthermore, the rigidity of the casing can be further increased. Furthermore, the present invention may be implemented by appropriately combining the structures disclosed in the foregoing embodiments. It should be noted that the electric circuit according to the present invention may be formed on a surface of the casing other than the inner face thereof, such as an outer surface of the casing.

Moreover, specifications (such as sizes, shapes, locations and materials) for the casing, electric circuit, rib, concave groove, inner face (surface), conductive adhesive, etc. are not limited to the foregoing embodiments, but may be appropriately changed in implementing the present invention. Furthermore, the conductive adhesive may be brought into conduction with a conductive material (such as a metal material, for example) inside the casing via a screw or the like made of a conductive material such as a metal material, thus providing a structure connected to the ground.

An electronic device of the present invention is not limited to a portable computer, but may be implemented as a device such as a television receiver, for example.

Although the embodiments according to the present invention have been described above, the present invention may not be limited to the above-mentioned embodiments but can be variously modified. Components disclosed in the aforementioned embodiments may be combined suitably to form various modifications. For example, some of all components disclosed in the embodiments may be removed or may be appropriately combined.

Additional advantages and modifications will readily occur to those skilled in the art. Therefore, the invention in its broader aspects may not be limited to the specific details and representative embodiments shown and described herein. Accordingly, various modifications may be made without departing from the spirit or scope of the general inventive concept as defined by the appended claims and their equivalents.

1. An electronic device comprising:
an insulating casing having a horizontal grove comprising a first wall part and a second wall part that extends in a direction intersecting the first wall part, the horizontal groove extending in a horizontal direction along an inner surface of the insulating casing;
a contained component contained in the horizontal groove; and
a conductive adhesive applied within the horizontal groove to extend in the horizontal direction, the conductive adhesive comprising a first end portion being electrically connected to the contained component and a second end portion provided at a position different from that of the first end portion.

2. The device of claim 1,
wherein the casing comprises an inner face portion continuous with an end portion of the second wall part, which is located away from the first wall part, and
wherein the contained component comprises a mounting height located between the end portion of the second wall part and the inner face portion.

3. The electronic device of claim 2,
wherein the second wall part comprises a pair of wall parts extended upward from the first wall part and opposed to each other, and
wherein the contained component is located between the pair of wall parts.

4. The device of claim 3,
wherein the first wall part is a bottom wall of a concave portion provided at the inner face portion of the casing, and the second wall part is provided at the peripheral edge of the bottom wall and extended across the bottom wall and the inner face portion of the casing.

5. The device of claim 4,
wherein the second wall part is extended along a region where the conductive adhesive is applied.

6. The device of claim 2,
wherein the casing is provided with a ground portion, and the second end portion of the conductive adhesive is connected to the ground portion.

7. The device of claim 2,
wherein the casing contains an another contained component, and the second end portion of the conductive adhesive is electrically connected to the another contained component.

8. The device of claim 2,
wherein the second wall part comprises opposing surface portions opposed to a pair of side portions of the contained component, constituting a corner portion thereof.

9. An device comprising:
an insulating casing comprising an inner face portion, and a pair of protruded parts opposed to each other and protruded from the inner face portion;
a first contained component contained in the casing and located between the pair of protruded parts;
a second contained component contained in the casing and located between the pair of protruded parts; and
a conductive adhesive which is located between the pair of protruded parts and through which the first and second contained components are electrically connected.

10. The device of claim 9,
wherein the pair of protruded parts are extended along a region where the conductive adhesive is applied.
